(19) United States
(12) Patent Application Publication
(10) Pub. No.: US 2025/0125232 A1
(43) Pub. Date: Apr. 17, 2025

(54) WETTABLE METALIZATION MULTILAYER WITH INCREASED ADHESION ENERGY, INTEGRATED ELECTRONIC DEVICE HAVING A WETTABLE METALIZATION MULTILAYER AND MANUFACTURING PROCESS

(71) Applicant: STMicroelectronics International N.V., Geneva (CH)

(72) Inventors: Brunella CAFRA, Mascalucia (IT); Antonio LANDI, Scordia (IT); Agata GRASSO, Tremestieri Etneo (IT); Crocifisso Marco Antonio RENNA, Floridia (IT)

(73) Assignee: STMicroelectronics International N.V., Geneva (CH)

(21) Appl. No.: 18/910,748

(22) Filed: Oct. 9, 2024

(30) Foreign Application Priority Data
Oct. 17, 2023 (IT) 102023000021621

(51) Int. Cl. H01L 23/495

(52) U.S. Cl. CPC H01L 23/49582; H01L 23/49575

(57) ABSTRACT

Wettable metalization multilayer formed by an adhesion layer, containing titanium; a barrier layer, containing nickel; and a sintering layer, containing silver. A portion of the sintering layer, facing the barrier layer, contains atoms of a metal material chosen between aluminum and tin. A portion of the barrier layer facing the sintering layer may contain atoms of the metal material. The sintering layer is obtained depositing by PVD and spinning a metal material layer and then a silver layer, causing the diffusion of the atoms of the metal material in the silver layer.

### BACKGROUND

### Technical Field

The present disclosure relates to a wettable or brazable metalization multilayer with increased adhesion energy, to an integrated electronic device having a wettable metalization multilayer, and to the manufacturing process of the wettable metalization multilayer.

### Description of Related Art

As is known, integrated electronic devices are coupled to the outside through connection regions, for example contact pads, of highly conductive material, typically metal. Connection regions allow bonding of electrical connectors, such as wires, ribbons or clips, which electrically connect active and passive regions of the integrated electronic device to the outside, e.g., with conductive tracks formed on or in a printed circuit board or other supports.

The highly conductive material forming the connection regions typically include multiple layers of different metal species, further forming a wettable layer stack. The top metal layer of the wettable layer stack facilitates bonding with the electrical connectors, however, oxidation at the bottom surface of the top metal layer is known to impede adhesion between the top metal layer and lower metal layers. The oxidation process of this bottom surface may occur by oxygen adsorption, dissociation, dissolution, and diffusion through the top metal layer. Overall, oxidation at the bottom surface may cause the top metal layer to lift-off and detach from the lower metal layers, which may prevent bonding of the electrical connectors to the device.

Currently, various approaches have been tried to limit the indicated detachment phenomenon, including better controlling chamber environments to reduce the presence of oxygen, increasing the thickness of the top metal layer of the wettable layer stack, and improving the topography and, in particular, the planarity of the device's surface, but none of them has been decisive.

### Brief Summary

According to the present disclosure, a wettable metalization multilayer on an integrated electronic device is provided. A wettable metalization multilayer first includes an adhesion layer containing titanium. A barrier layer containing nickel is disposed on the adhesion layer, and an intermetallic layer, containing a metal material of either aluminum or tin, is further disposed on the barrier layer. A sintering layer is then positioned on the intermetallic layer, where the formation of the sintering layer includes a diffusion process between atoms of the intermetallic layer and atoms of the respective barrier and sintering layers.

According to the present disclosure, a manufacturing process for an integrated electronic device which includes a wettable metalization multilayer is provided. A process for manufacturing an integrated electronic device, which first includes forming an adhesion layer, containing titanium, on a front side of a semiconductor substrate. Forming a barrier layer, containing nickel, on the adhesion layer, and, subsequently, forming an intermetallic layer containing a metal material chosen between aluminum and tin, on the barrier layer. Finally, a sintering layer, containing silver, is formed on the intermetallic layer, wherein forming a sintering layer includes causing atoms of the intermetallic layer to diffuse into both the sintering layer and the barrier layer.

The present disclosure provides a solution that allows forming a wettable layer stack containing Ag (Silver) and NiV (Nickel vanadium) or Ni (Nickel) which does not have the delamination and detachment problem described above.

### BRIEF DESCRIPTION OF THE SEVERAL VIEWS OF THE DRAWINGS

For a better understanding of the present disclosure, an embodiment is now described, purely by way of non-limiting example, with reference to the attached drawings, wherein:

FIG. 1 shows a cross-section of a power MOSFET device having an external connection wettable layer;

FIG. 2 shows a cross-section of a wettable layer of an integrated electronic device, on an enlarged scale;

FIG. 3 is a schematic representation of the oxygen atoms diffusion mechanism in a silver layer;

FIGS. 4A-4D show cross-sections, similar to FIG. 2, of an embodiment of a process for manufacturing an integrated electronic device having a wettable layer, in successive steps;

FIGS. 5A and 5B show atom distribution profiles obtained through Auger analysis for the wettable layer of FIG. 2;

FIGS. 6A and 6B showing atom distribution profiles obtained through Auger analysis for the wettable layer of FIG. 4C; and

FIG. 7 is a flow diagram of an embodiment of a manufacturing process of the integrated electronic device of FIG. 4D.

### DETAILED DESCRIPTION

The following description refers to the arrangement shown; consequently, expressions such as “above”, “below”, “upper”, “lower”, are relative to the attached Figures and should not be interpreted in a limiting manner.

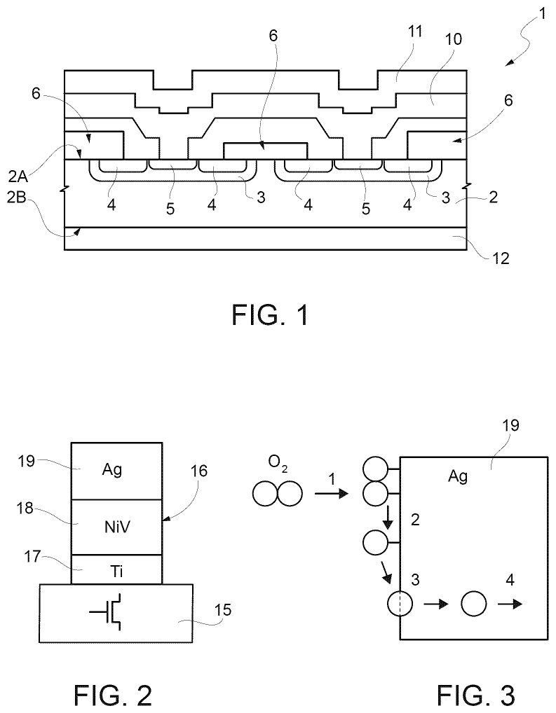

FIG. 1 shows a MOSFET transistor 1 formed in a substrate 2, of semiconductor material and of a first conductivity type, for example of N-type, having a front surface 2A and a back surface 2B. The substrate 2 accommodates body regions 3. In turn, the body regions 3, of a second conductivity type opposite to the first conductivity type, for example of P-type, accommodate source regions 4, of the first conductivity type, and body contact regions 5, of the second conductivity type and dopant concentration greater than the body regions 3. Insulated gate regions 6 are positioned over the front surface 2A of the substrate 2, astride between two adjacent body regions 3. A source metalization layer 10 covers the front surface 2A of the substrate 2, where exposed, and the insulated gate regions 6. A wettable layer 11 covers the source metalization layer 10.

For example, the source metalization layer 10 is formed by a plurality of layers, such as layers of titanium Ti and a copper-based alloy (for example AlSiCu), and the wettable layer 11 includes silver Ag, as discussed below.

The back surface 2B of the substrate 2 is covered by a drain metalization 12, for example formed by a plurality of layers including titanium Ti, nickel-vanadium NiV or nickel Ni and silver Ag (hereinafter referred to as metalization multilayer or stack).

Currently, for forming the contact regions arranged on the front side of electronic devices based on silicon, silicon carbide and gallium nitride (for example forming the wettable layer 11 of FIG. 1), stacks of different metals are used, which ensure good adhesion both to the surface of the integrated device and to the wires, ribbons and connection clips (hereinafter, for the sake of simplicity, when reference is made to wires, flatter structures, such as ribbons, clips and the like are also included).

For example, a stack of metal layers currently widely used for forming the wettable layer 11 includes three layers, as shown in FIG. 2.

FIG. 2 shows a device 15, represented by a transistor, which may for example include the substrate 2 and regions and layers integrated in the substrate 2 and on the substrate 2, including the source metalization layer 10 of FIG. 1.

A wettable layer 16, corresponding to the wettable layer 11 of FIG. 1, is positioned on the device 15 and is formed by a stack of layers including a first layer 17, for example of titanium Ti or chromium Cr; a second layer 18, for example of an alloy of nickel-vanadium NiV or of only nickel Ni, and a third layer 19, of silver Ag.

In some cases, an additional layer of nickel Ni may be provided between the second layer 18 and the third layer 19 or the second layer 18 may include only nickel.

The first layer 17 has the function of providing a good adhesion of the wettable layer 16 to the device 15, for example to the source metalization 10 of FIG. 1; the third layer 19, if it includes silver, has the function of allowing a good sintering process between the third layer 19, and a wire or other external electrical connector; and the second layer 18 operates as a diffusive barrier between the first layer 17 and the third layer 19.

In case of a layer stack with the third layer 19 of silver, however, in some cases insufficient adhesion to the nickel-vanadium alloy or the nickel layer occurred. In such cases, during sintering, the third layer 19 of silver lifted completely, exposing the underlying second layer 18.

Depth profile analyzes by Auger electron spectroscopy (AES) through the wettable layer 16 on samples having poor adhesion show the presence of oxygen at the NiV/Ag interface; this oxygen is not present after depositing the third layer 19.

Furthermore, analysis using EDX (Energy Dispersive X-ray) spectroscopy and carried out on the delaminated layer and on the surface of the device remained after the detachment show that the delamination occurs between the NiV layer and the Ag layer.

NiV oxidation is also known to reduce the interfacial adhesion energy between NiV and Ag; this reduction in the adhesion energy may therefore cause lift-off of the third layer 19, of silver, and consequently the detachment of the wires and failure of the device.

It has also been demonstrated that NiV oxidation is due to the fact that silver is not an efficient barrier to the diffusion of oxygen. This is represented in FIG. 3 which shows the behavior of a silver layer in presence of oxygen and in particular shows that the penetration of oxygen atoms into a silver layer occurs in four steps:
1. adsorption of O₂ molecules;
2. dissociation of molecules into oxygen atoms;
3. dissolution of oxygen atoms along the surface of the silver layer; and
4. diffusion of oxygen atoms in the silver layer towards the surface opposite to the penetration one.

Studies show that the diffusion speed increases with temperature (by a few hours in the case of room temperature; by a few minutes at 250° C.).

It has also been seen that increasing the thickness of the silver layer is not decisive.

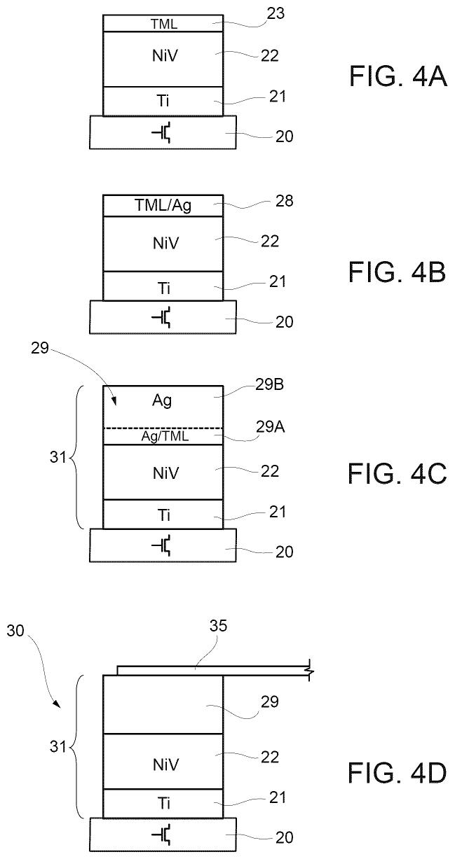

FIGS. 4A-4D schematically show manufacturing steps of an integrated electronic device 30.

In particular, FIG. 4A shows a semi-finished electronic device 20 after forming active and passive structures in a substrate of semiconductor material not shown (for example similar to the substrate 2 of FIG. 1) and surface structures above the substrate (for example, the insulated gate regions 6 and the source metalization layer 10 of FIG. 1), before forming a wettable layer. The semi-finished electronic device 20 is represented, by way of example only, by a MOSFET transistor, although the following description also applies to integrated electronic devices of different type, having Si, SiC, or GaN substrates and intended to have a wettable layer includes a layer containing Ag.

In FIG. 4A, an adhesion layer 21, a barrier layer 22, and a metal layer, hereinafter referred to as intermetallic layer 23, have already been deposited, in succession, on the semi-finished electronic device 20.

The adhesion layer 21 is similar to the first layer 17 of FIG. 2, is of titanium Ti and has a thickness of 100-500 nm.

The barrier layer 22 is similar to the second layer 18 of FIG. 2, is of nickel-vanadium NiV or nickel Ni and has a thickness of 300-1000 nm.

The intermetallic layer 23 is a thin, low-melting metal layer, indicated in FIG. 4A by TML, capable of increasing the interfacial adhesion between the barrier layer 22 of NiV or Ni and a sintering layer containing Ag (to be formed).

The intermetallic layer 23 is formed by vapor-phase deposition PVD of a metal chosen between aluminum Al and tin Sn.

For example, the intermetallic layer 23, if it includes aluminum, has a thickness of 20-50 nm, and is deposited by sputtering at a power of 500-1000 W at a temperature not exceeding 200° C., preferably 150-200° C.

A sintering layer 29 is deposited on the intermetallic layer 23 (FIG. 4C). The sintering layer 29 is deposited by sputtering, in a dedicated chamber and without interrupting the vacuum conditions.

The deposition step of the sintering layer 29 may occur under the same conditions as the deposition of the intermetallic layer 23, and therefore at a temperature lower than 200° C., with sputtering power of 500-1000 W, and chamber pressure of 0.6-1 mtorr.

The sintering layer 29, at the end of the deposition, has a thickness variable between 300 and 500 nm.

The deposition conditions of the sintering layer 29 and, in particular, the temperature used lead to the interdiffusion of the atoms/molecules of the intermetallic layer 23 within the silver layer (sintering layer 29) forming an intermetallic.

This process is represented by FIGS. 4B and 4C showing the growth step of the sintering layer 29.

In FIG. 4B, a growth layer 28, resulting from the interdiffusion between the material of the intermetallic layer (23 in FIG. 4A and here no longer visible) and the material of the sintering layer 29 that is deposited, is formed above the barrier layer 22 in an initial deposition step, by PVD of the sintering layer. In particular, the growth layer 28 includes atoms of the metallic material TML (here aluminum but also Sn) and silver atoms.

Proceeding with the deposition of the sintering layer 29, the interdiffusion is reduced and the growth layer gradually has an increasingly smaller percentage of atoms of the metallic material TML as shown in FIG. 6B, discussed below; in particular, at the end of the growth, the sintering layer obtained, indicated by 29, may have a surface portion (29B in FIG. 4C) including the wettable material (silver) and a lower portion, in contact with the barrier layer 22 and indicated by 29A in FIG. 4C, containing both Ag atoms and TML atoms.

In practice, the thickness ratio between the deposited intermetallic layer 23 and the deposited sintering layer 29 is between 1:25 and 4:25, in particular 2:25.

Note that the interdiffusion phenomenon of the atoms of the metallic material TML may occur not only upwards, to form the sintering layer 29, but also (due to the temperature used during the deposition of the sintering layer 29), downwards, within the barrier layer 22, whose surface portion in contact with the sintering layer 29 typically also has atoms of the metallic material TML (see FIG. 6A). In a manner not shown, therefore, at the end of the growth process of the sintering layer, the barrier layer 22 may also have a surface portion with a different composition compared to the lower portion (in contact with the adhesion layer 21).

At the end of the deposition of the sintering layer 29, a layer stack 31 (also referred to as metalization multilayer) is present above the semi-finished electronic device 20.

FIG. 4D shows a final electronic device 30, after sintering an external connector 35, for example a clip, on the sintering layer 29.

Forming an intermetallic layer including the atoms of the metal material TML on the interface between the barrier layer 22 and the sintering layer 29 (and therefore, within the facing portions of both layers 22, 29) has a dual effect:
1) 1) increases the adhesion force between the barrier layer 22 of NiV or Ni and the sintering layer 29 of Ag due to the simultaneous presence of NiV or Ni and TML on the surface of NiV or Ni; and2) prevents oxygen from reaching the interface to the barrier layer 22 of NiV or Ni, since it remains trapped or confined at the very beginning (surface portion 28 in FIG. 4C) of the silver layer due to the trapping by the TML atoms at the interface between the surface portion 29B and the lower portion 29A of the sintering layer 29 in FIG. 4C.

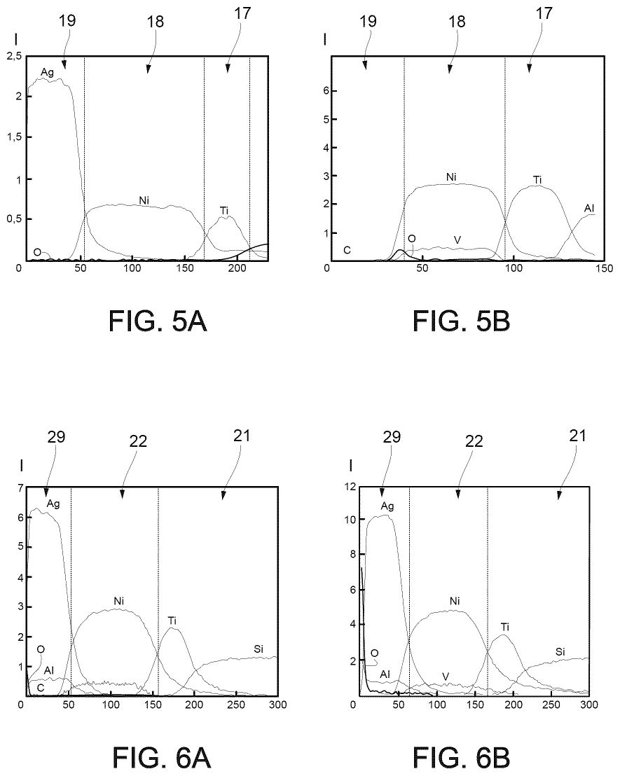

The optimum resistance to oxygen penetration in the layer stack 31 is demonstrated by the comparison of the curves shown in FIGS. 5A, 5B, 6A and 6B, showing atom distribution profiles obtained through Auger analysis.

In detail, FIGS. 5A and 5B show the profiles of atoms in the layer stack 16 of FIG. 2, i.e., without the deposition of an intermetallic layer, respectively before and after a provocation step (thermal treatment at 250° C. for 4 hours, in a nitrogen-rich environment).

FIG. 5B, in particular, shows a non-negligible percentage of O₂ which has penetrated and concentrated on the front surface of the NiV layer (second layer 18).

FIGS. 6A and 6B show the profiles of atoms present in the layer stack 31 of FIG. 4C, wherein the atoms of the metallic material TML are diffused both in the wettable layer 29 and in the upper part of the barrier layer 22, respectively before and after the provocation step, carried out under the same conditions indicated above.

FIG. 6B, in particular, shows the presence of O₂ atoms in significant amounts only on the surface part of the sintering layer 29; the rest of the sintering layer 29 and the barrier layer 22 instead have very low percentages of O₂, demonstrating the optimum shielding action of the atoms of the metallic material TML (here Al).

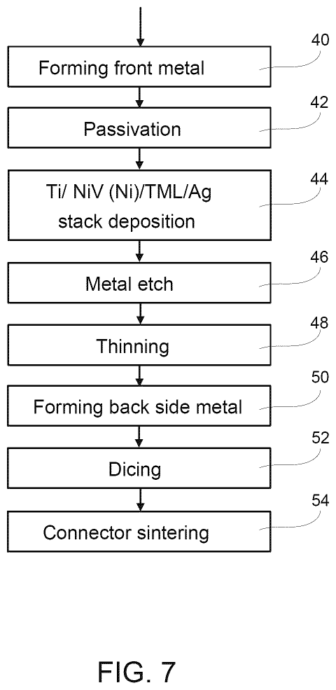

FIG. 7 shows a flow diagram of the final manufacturing steps of the integrated electronic device 30 of FIG. 4D.

After manufacturing the active and passive structures within and on the substrate (for example regions 3-6 of FIG. 1), a front metal layer is formed, for example of AlSiCu (for example the source metalization 11 of FIG. 1), step 40.

In step 42, spinning is performed for depositing a passivation layer, for example of polyimide.

After forming the openings in the passivation layer, the layer stack 31 is grown, step 44, depositing the adhesion layer 21, of titanium, the barrier layer 22, of NiV or Ni, the intermetallic layer 23 and the sintering layer 29, of Ag, according to what indicated above.

In step 46, the layer stack 31 is etched, for patterning the external contact regions (for example, contact pads).

In step 48, the device is thinned by grinding.

In step 50, a back metalization is deposited, for example the drain metalization 12 of FIG. 1.

Then dicing is performed, for example by sawing, to form single dice, step 52.

In step 54, the die 30 is attached to a support (die attach step) and then one or more external connectors, such as the clip 35 of FIG. 4D, are sintered. This sintering occurs by dispensing a special sintering paste, for example a commercial product for silver sintering die attach. The final integrated electronic device is thus obtained.

The layer stack 31 formed by the wettable layer and the integrated electronic device 30 having such layer stack have numerous advantages, as evident from the foregoing.

In particular, studies by the Applicant have shown that the presence of the material TML allows an increase in the adhesion energy between the barrier layer 22 and the sintering layer 29, of silver, such as to safely avoid the detachment of the sintering layer 29.

Finally, it is clear that modifications and variations may be made to the metalization multilayer, and the device described and illustrated herein without thereby departing from the scope of the present disclosure, as defined in the attached claims.

For example, as indicated, the barrier layer 22 may be made by a single NiV layer or by a Ni layer; the deposition parameters of the material TML may vary.

As indicated, in some cases a thin layer of a few nanometers of the material TML of the intermetallic layer 23 may remain between the barrier layer 22 and the sintering layer 29 and the sintering layer 29 may include atoms of the material TML in a portion of or throughout its thickness.

A wettable metalization multilayer (31) may be summarized as including: an adhesion layer (21), containing titanium; a barrier layer (22), containing nickel; a sintering layer (29), containing silver, wherein a portion of the sintering layer (29) facing the barrier layer (22) contains atoms of a metal material chosen between aluminum and tin.

A portion of the barrier layer (22) facing the sintering layer (29) may contain atoms of the metal material.

The sintering layer (29) may have a thickness comprised between 300 and 500 nm.

The barrier layer (22) may have a thickness comprised between 300 and 1000 nm.

An intermetallic layer (23), of the metal material, may extend between the barrier layer (22) and the sintering layer (29).

An integrated electronic device, may be summarized as including a substrate (2) having a front surface (2A) and a back surface (2B) and external contact structures (11) extending on the front surface (2A) of the substrate (2), wherein the contact structures (11) include a wettable metalization multilayer (31).

The integrated electronic device may further include connection clips (35) sintered to the sintering layer (29).

A process for manufacturing an integrated electronic device (30), may be summarized as including: forming an adhesion layer (21), containing titanium, on a front side (2A) of a substrate (2) of semiconductor material; forming a barrier layer (22), containing nickel, on the adhesion layer (21); forming a metal layer (23) containing a metal material chosen between aluminum and tin, on the barrier layer (22), and growing a sintering layer (29), containing silver, on the metal material layer (23), wherein growing a sintering layer (29) includes causing atoms of the metal material to diffuse into the sintering layer.

Growing a sintering layer (29) may include causing atoms of the metal material to diffuse into the barrier layer (22).

Forming a metal material layer (23) may include depositing the metal material by PVD.

The metal layer (23) may be deposited for a thickness of 20-50 nm, preferably at a power of 500-1000 W and at a temperature lower than 200° C.

The sintering layer (29) may be deposited for a thickness of 300-500 nm, preferably at a power of 500-1000 W and at a temperature comprised between 150-200° C.

The process may further include bonding an external connector (35) by sintering to the sintering layer (29).

The thickness ratio between the metal layer (23) and the sintering layer (29) may be between 1:25 and 4:25, preferably 2:25.

Forming a metal material layer (23) and growing a sintering layer (29) may be performed by sputtering in a same deposition system and without vacuum interruption.

A wettable metalization multilayer (31), including: an adhesion layer (21), containing titanium; a barrier layer (22), containing nickel, formed on the adhesion layer (21); an intermetallic layer (23), containing a metal material chosen between aluminum and tin, formed on the barrier layer (22); and a sintering layer (29), containing silver, formed on the intermetallic layer (23), wherein formation of the sintering layer (29) is configured to initiate a diffusion process between atoms of the intermetallic layer (23) and atoms of the respective barrier (22) and sintering (29) layers.

The intermetallic layer (23) has a thickness between 20 and 50 nm.

The sintering layer (29) has a thickness between 300 and 500 nm.

The barrier layer (22) has a thickness between 300 and 1000 nm.

The diffusion process between atoms of the intermetallic layer (23) and atoms of the respective barrier (22) and sintering (29) layers occurs during a physical vapor deposition of the sintering layer (29) at a temperature below 200° C.

An integrated electronic device (30), further including a substrate (2) having a front surface (2A) and a back surface (2B) and external contact structures (11) positioned on the front surface (2A) of the substrate (2), wherein the contact structures (11) include the wettable metalization multilayer (31).

The integrated electronic device (30) further includes connection clips (35) sintered to the sintering layer (29).

A process for manufacturing an integrated electronic device (30) comprising: forming an adhesion layer (21), containing titanium, on a front side (2A) of a semiconductor substrate (2); forming a barrier layer (22), containing nickel, on the adhesion layer (21); forming an intermetallic layer (23) containing a metal material chosen between aluminum and tin, on the barrier layer (22); and forming a sintering layer (29), containing silver, on the intermetallic layer (23), wherein forming the sintering layer (29) includes causing atoms of the intermetallic layer (23) to diffuse into the respective sintering (29) and barrier (22) layers.

The sintering layer (29) contains increasingly smaller concentrations of atoms of the intermetallic layer (23) as distance from the intermetallic layer (23) increases. Forming the intermetallic layer (23) includes depositing the metal material by physical vapor deposition.

The intermetallic layer (23) is deposited for a thickness of 20-50 nm, preferably at a power of 500-1000 W and at a temperature lower than 200° C.

The sintering layer (29) is deposited for a thickness of 300-500 nm, preferably at a power of 500-1000 W and at a temperature between 150-200° C.

Forming the integrated electronic device (30) further includes bonding an external connector (35) by sintering to the sintering layer (29).

A thickness ratio between the intermetallic layer (23) and the sintering layer (29) is between 1:25 and 4:25, preferably 2:25.

Forming the intermetallic layer (23) and forming the sintering layer (29) are performed by sputtering in a same deposition system and without vacuum interruption.

A wettable connection multilayer (31), comprising: an adhesion layer (21), containing titanium, formed over a source metalization layer (10) and positioned on a front side (2A) of a semiconductor substrate (2); a barrier layer (22), containing nickel, formed on the adhesion layer (21); a sintering layer (29), containing silver, formed on the barrier layer (22), wherein a portion of the sintering layer (29) facing the barrier layer (22) contains atoms of an intermetallic layer (23), including one of either aluminum or tin, and wherein a portion of the barrier layer (22) facing the sintering layer (29) contains atoms of the intermetallic layer (23); and a connection clip (35) sintered to the sintering layer (29).

The source metalization layer (10) is coupled to a transistor (1) included on the semiconductor substrate (2).

The intermetallic layer (23) is formed on the barrier layer (22), and the sintering layer (29) is formed on the intermetallic layer (23), and wherein formation of the sintering layer (29) includes causing atoms of the intermetallic layer (23) to diffuse into the respective sintering (29) and barrier (22) layers.

The sintering layer (29) has a thickness between 300 and 500 nm.

The barrier layer (22) has a thickness between 300 and 1000 nm.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A wettable metalization multilayer, comprising:
an adhesion layer, containing titanium;
a barrier layer, containing nickel, on the adhesion layer;
an intermetallic layer, containing a metal material chosen between aluminum and tin, on the barrier layer; and
a sintering layer, containing silver, on the intermetallic layer,
wherein the sintering layer is configured to initiate a diffusion process between atoms of the intermetallic layer and atoms of the barrier layer and the sintering layer.

2. The metalization multilayer according to claim 1, wherein the intermetallic layer has a thickness between 20 and 50 nm.

3. The metalization multilayer according to claim 1, wherein the sintering layer has a thickness between 300 and 500 nm.

4. The metalization multilayer according to claim 1, wherein the barrier layer has a thickness between 300 and 1000 nm.

5. The metalization multilayer according to claim 1, wherein the diffusion process between atoms of the intermetallic layer and atoms of the barrier layer and the sintering layer occurs during a physical vapor deposition of the sintering layer at a temperature below 200° C.

6. An integrated electronic device, comprising:
a wettable metalization multilayer, that includes:
an adhesion layer, containing titanium;
a barrier layer, containing nickel, on the adhesion layer;
an intermetallic layer, containing a metal material chosen between aluminum and tin, on the barrier layer; and
a sintering layer, containing silver, on the intermetallic layer,
wherein the sintering layer is configured to initiate a diffusion process between atoms of the intermetallic layer and atoms of the barrier layer and the sintering layer;
a substrate having a front surface and a back surface and external contact structures positioned on the front surface of the substrate, wherein the contact structures include the wettable metalization multilayer.

7. The integrated electronic device according to claim 6, further including connection clips sintered to the sintering layer.

8. A process for manufacturing an integrated electronic device, comprising:
forming an adhesion layer, containing titanium, on a front side of a semiconductor substrate;
forming a barrier layer, containing nickel, on the adhesion layer;
forming an intermetallic layer containing a metal material chosen between aluminum and tin, on the barrier layer; and
forming a sintering layer, containing silver, on the intermetallic layer,
wherein forming the sintering layer includes causing atoms of the intermetallic layer to diffuse into the sintering layer and the barrier layer.

9. The process according to claim 8, wherein the sintering layer contains increasingly smaller concentrations of atoms of the intermetallic layer as distance from the intermetallic layer increases.

10. The process according to claim 8, wherein forming the intermetallic layer includes depositing the metal material by physical vapor deposition.

11. The process according to claim 8, wherein the intermetallic layer is deposited for a thickness of 20-50 nm, preferably at a power of 500-1000 W and at a temperature lower than 200° C.

12. The process according to claim 8, wherein the sintering layer is deposited for a thickness of 300-500 nm, preferably at a power of 500-1000 W and at a temperature between 150-200° C.

13. The process according to claim 8, wherein forming the integrated electronic device further includes bonding an external connector by sintering to the sintering layer.

14. The process according to claim 8, wherein a thickness ratio between the intermetallic layer and the sintering layer is between 1:25 and 4:25, preferably 2:25.

15. The process according to claim 8, wherein forming the intermetallic layer and forming the sintering layer are performed by sputtering in a same deposition system and without vacuum interruption.

16. A device, comprising:
a wettable connection multilayer that includes:
an adhesion layer, containing titanium, over a source metalization layer and on a front side of a semiconductor substrate;
a barrier layer, containing nickel, on the adhesion layer;
a sintering layer, containing silver, on the barrier layer,
an intermetallic layer, including one of either aluminum or tin, a portion of the sintering layer facing the barrier layer contains atoms of the intermetallic layer, a portion of the barrier layer facing the sintering layer contains atoms of the intermetallic layer; and
a connection clip sintered to the sintering layer.

17. The device according to claim 16, wherein the source metalization layer is coupled to a transistor included on the semiconductor substrate.

18. The device according to claim 16, wherein the intermetallic layer is on the barrier layer, and the sintering layer is on the intermetallic layer, the sintering layer is configured to cause atoms of the intermetallic layer to diffuse into the sintering layer and the barrier layer.

19. The device according to claim 16, wherein the sintering layer has a thickness between 300 and 500 nm.

20. The device according to claim 16, wherein the barrier layer has a thickness between 300 and 1000 nm.
